(19) United States
(12) Patent Application Publication
(10) Pub. No.: US 2005/0285248 A1
(43) Pub. Date: Dec. 29, 2005

(54) Method and system for expanding flash storage device capacity

(76) Inventors: Sun-Teck See, San Jose, CA (US); Horng-Yee Chou, Palo Alto, CA (US); Charles C. Lee, Sunnyvale, CA (US)

Correspondence Address: SAWYER LAW GROUP LLP, P.O. Box 51418, Palo Alto, CA, 94303, US

(21) Appl. No.: 10/881,203

(22) Filed: Jun. 29, 2004

(51) Int. Cl. H01L 23/02

(52) U.S. Cl. 257/681; 257/685; 257/686; 257/777

(57) ABSTRACT

A memory package and a chip architecture which includes stacked multiple memory chips is described. In a first aspect, a memory package comprises a substrate and a plurality of memory dies mounted on the substrate. Each die has a separate chip enable. In a second aspect, a chip architecture comprises a printed circuit board (PCB). The PCB includes a footprint. The footprint includes at least one no connect (NC) pad. The chip architecture includes a plurality of stacked memory chips mounted on the printed circuit board. Each of the plurality of stacked memory has a chip enable signal pin and also has at least one NC pin. At least one of the plurality of stacked memory chips utilizes an NC pin of another of the stacked memory chips to route the chip enable pin to at least one NC pad of the footprint. Accordingly, a system and method in accordance with the present invention provides for increased memory density within a particular space constraint by (1) providing multiple dies in a single memory package and (2) by providing stacked memory chips in a single PCB footprint. In so doing, the package/PCB will have increased memory density over a conventional package/PCB within the same space constraints, and the capacity of Flash storage devices is expanded accordingly.

### FIELD OF THE INVENTION

The present invention relates generally to memories and more particularly to a system and method for expanding the capacity of Flash storage devices.

### BACKGROUND OF THE INVENTION

The nature of non-volatile, vibration-free, small size and low power consumption has made the Flash memory an excellent component to be utilized in various Flash storage devices. Flash storage devices are widely used as memory storage for computer and consumer system products such as notebook, desktop computer, set top box, digital camera, mobile phone, PDA and GPS etc. The increasing demand for more storage in these products has driven the need to expand the capacity of the Flash storage devices.

There are two types of Flash storage devices. The first type has a pre-defined mechanical dimension. This type includes: (a) Secure Digital (SD) card, (b) Multi Media Card (MMC), (c) Memory Stick (MS) card, (d) Compact Flash (CF) card, (e) Express Flash card, (f) Serial ATA Flash disk, (g) IDE Flash disk, (h) SCSI Flash disk, etc.

The second type of Flash storage devices has no pre-defined physical dimension, which includes USB Flash disk, Disk On Module (DOM), MP3 player etc. However, corresponding based upon the need for the system compactness, it is generally desirable to make this type of Flash storage device as small in size and as high in capacity as possible.

Space constraints and available Flash memory density are the major obstacles in expanding the capacity of the Flash storage devices. FIG. 1 illustrates top, bottom, short side lateral and long side lateral views of a secure digital (SD) card 10. The SD card 10 is defined with a form factor of 32×24×2.1 mm (length×width×thick). This fixed dimension restricts the number of components populated on a printed circuit board (PCB) 12. For instance, if TSOP type of Flash memory is used, only a Flash memory chip 14 and a Flash controller 16 can be placed in the space constraint. The available Flash memory density further limits the overall SD card capacity. For instance, if the highest Flash memory is 4 Gb, the maximum SD card capacity is then limited to 512 MB.

A Flash memory die is the basic element of Flash memory. A typical Flash memory chip comprises a Flash memory die mounted on a substrate within an enclosure and the electrical signals are bonded out to the metal contacts of the package. FIG. 2 illustrates a Flash memory chip 50 in a thin, small out-line package (TSOP). The popular package types for flash memory chip are TSOP (Thin Small Out-line Package), WSOP (Very Very Thin Small Out-line Package) and BGA (Ball Grid Array) etc. For the purposes of this application, Flash memory will be used to describe both a Flash memory die and a Flash memory chip.

Besides power and ground, a flash memory includes the following electrical signals:

(a) Bidirectional signals: I/O (Input/Output) bus. It is a bidirectional bus. Flash memory uses this bus to input command, address and data, and to output data during read operation. Multiple Flash memories can share this bus with a Flash controller.

(b) Common Input Control Signals: ALE (Address Latch Enable), CLE (Command Latch Enable), RE—(Read Enable), WE—(Write Enable), WP—(Write Protect). Driven by Flash controller for various operations to Flash memory. These signals are shared among multiple Flash memories connected to a single I/O bus.

(c) Exclusive Input Control Signal: CE—(Chip Enable). Driven by Flash memory controller to enable the Flash memory for access. To ensure only one of them is enabled at a time, each Flash memory is connected to a unique CE-.

(d) Output Status Signals: R/B—(Ready/Busy-). Driven by Flash memory when it is busy, not ready to accept command from the Flash controller. It is an open-drain signal that can be shared among multiple Flash memories connecting to a single I/O bus.

The typical functional block diagram of a Flash storage device 80 is shown in FIG. 3. It comprises a Flash controller 82 and at least a Flash memory 84. One end of the Flash controller 82 interfaces to the host while the other end controls the access to Flash memory 84.

In many instances, due to cost and pin count considerations, a Flash controller has a limited number of chip enable signals. This limitation imposes a restriction on capacity expansion.

Furthermore, as the demand for Flash storage devices has increased, a shortage of certain types of Flash memory occurs during the course of a year. Flash types of the most popular density are typically out of supply during the peak seasons.

Accordingly it is desirable to provide ways to expand the capacity of Flash storage devices. The present invention addresses such a need.

### SUMMARY OF THE INVENTION

A memory package and a chip architecture which includes stacked multiple memory chips is described. In a first aspect, a memory package comprises a substrate and a plurality of memory dies mounted on the substrate. Each die has a separate chip enable. In a second aspect, a chip architecture comprises a printed circuit board (PCB). The PCB includes a footprint. The footprint includes at least one no connect (NC) pad. The chip architecture includes a plurality of stacked memory chips mounted on the printed circuit board. Each of the plurality of stacked memory has a chip enable signal pin and also has at least one NC pin. At least one of the plurality of stacked memory chips utilizes an NC pin of another of the stacked memory chips to route the chip enable pin to at least one NC pad of the footprint.

Accordingly, a system and method in accordance with the present invention provides for increased memory density within a particular space constraint by (1) providing multiple dies in a single memory package and (2) by providing stacked memory chips in a single PCB footprint. In so doing, the package/PCB will have increased memory density over a conventional package/PCB within the same space constraints, and the capacity of Flash storage devices is expanded accordingly.

### BRIEF DESCRIPTION OF THE DRAWINGS

FIG. 1 illustrates a top and bottom view of a secure digital card.

FIG. 2 illustrates a Flash memory chip in a thin, small out-line package (TSOP).

FIG. 3 illustrates a block diagram inside a conventional Flash storage device.

FIG. 4A-4C illustrates various ways to include multiple dies in a single package.

FIG. 5A illustrates a typical pin-out of a TSOP memory chip and its corresponding footprint on PCB layout.

FIG. 5B illustrates an example of the stacking of two Flash memory chips.

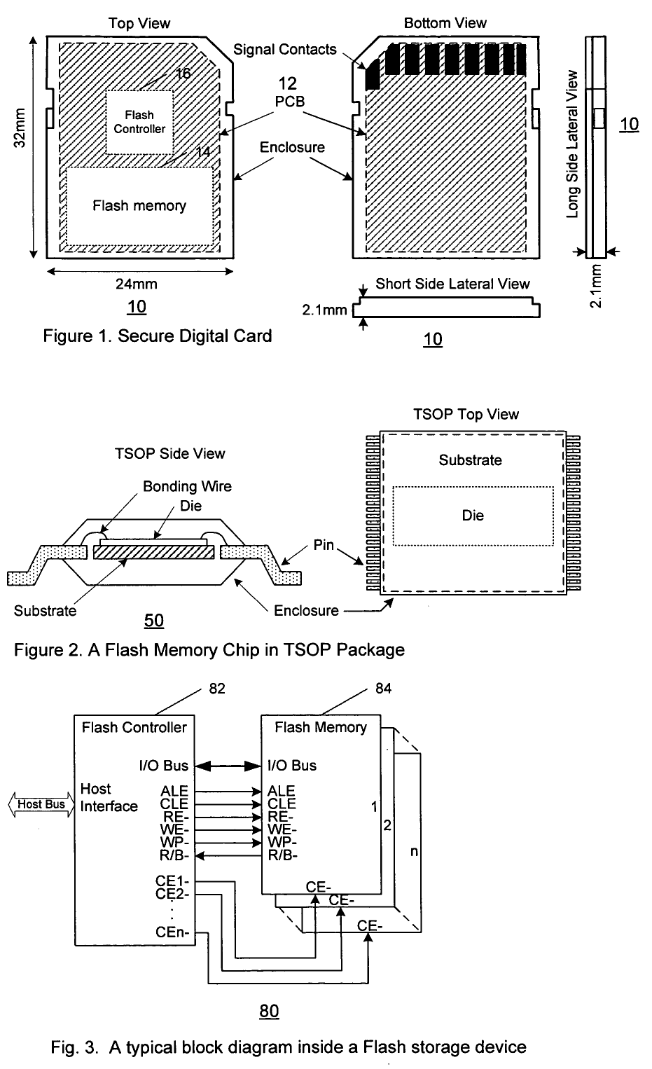

### DETAILED DESCRIPTION OF THE INVENTION

The present invention relates generally to memories and more particularly to a system and method for expanding the capacity of Flash storage devices. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown but is to be accorded the widest scope consistent with the principles and features described herein.

In the present invention, memory density is increased in a single package or a printed circuit board (PCB) by including more memory dies/chips on the same package/PCB. In so doing, the package/PCB will have increased memory density over a conventional package/PCB within the same space constraints. To describe the features of the present invention in more detail, refer now to the following discussion in conjunction with the accompanying Figures.

Multiple-Die in Single Package with Multiple Chip Enables

Accordingly as above mentioned a single package includes more than one die to increase the density of a Flash memory chip. Since a chip enable signal is required for each Flash memory die, the chip enable of each Flash memory die is bonded out to a pin of the package, hence resulting multiple chip enables in a single package.

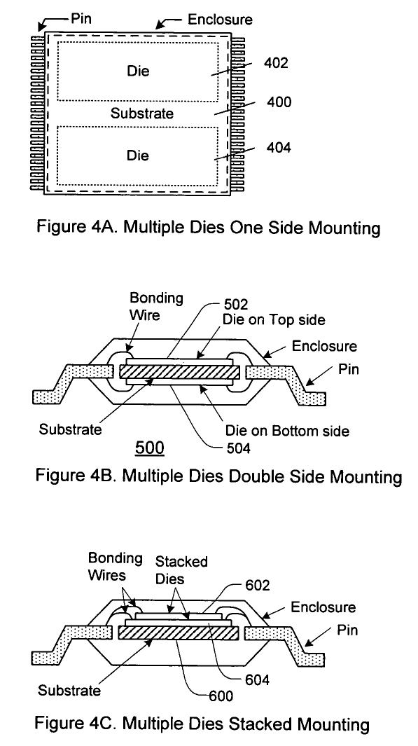

FIGS. 4A-4C illustrate various way to include multiple dies in a single package. In one embodiment, multiple dies 402-404 can be mounted on any one side of the substrate 400 as shown in FIG. 4A. In a second embodiment, multiple dies 502-504 can be achieved by double-side mounting of the substrate 500 as shown in FIG. 4B. In a third embodiment, additional dies can be included into the package by stacking the dies 602-604 to each other as shown in FIG. 4C. Two or more than two dies can be stacked together and the stacked dies can be mounted on any one side or both sides of the substrate 600.

Furthermore, the multiple-die Flash memory chip can be made of any combination of the above methods. Utilizing a system in accordance with the present invention, the Flash memory density is increased and the space constraint and available density issues are resolved.

Stacked Multiple Chips with Multiple Chip Enables

In stacked chip architecture, multiple Flash memory chips can be stacked together on a single footprint on a PCB in which the pads of the footprint are conformed to the pins of the Flash memory chip. Besides the first chip enable connected to the inherent pad, additional chip enables from Flash controller are connected to the NC pads corresponding to the NC (No Connect) pins of the Flash memory chip. While the first Flash memory chip soldered on the PCB receives the first chip enable from the inherent pad, each of the other stacked Flash memory chips receives its individual chip enable via the routing through different NC pads.

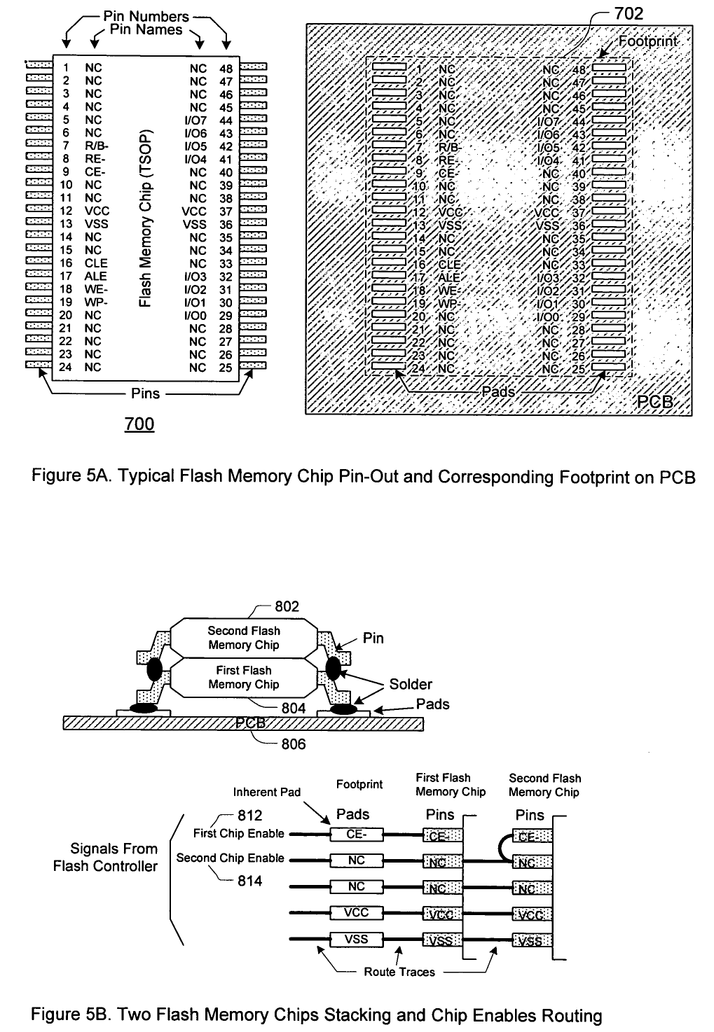

FIG. 5A shows a typical pin-out of a TSOP memory chip 700 and its corresponding footprint 702 on PCB layout. FIG. 5B shows an example of the stacking of two Flash memory chips 802-804. The first Flash memory chip 804 is soldered directly on the footprint 702 of the PCB 806, the second Flash memory chip 802 is stacked and soldered on the first Flash memory chip 804 in a pin to pin manner besides its chip enable pin, which is connected to the second chip enable via the routing through a NC pad. The routing of chip enables is shown in the bottom diagram. The first chip enable 812 is connected directly to the first Flash memory chip 804 through the inherent pad. The second chip enable 814 is routed to the second Flash memory chip 802 via NC pad and NC pins of the first and second Flash memory chips 804 and 802. The stacked chips can be installed on one of sides or both sides of the PCB 806.

The multiple stacked chips in accordance with the present invention resolves both the Flash memory density available and space constraints.

Multiple Downgraded Chips

A Flash memory die with excessive bad blocks may fails to meet on original class of density, however it can be made as a downgraded flash memory chip by altering its ID device code to register the new part number and density corresponding to its existing number of good blocks. Multiple downgraded Flash memory chips can be used to provide the desired capacity.

For example, a 1 Gb Flash memory which has defective blocks can be downgraded to 512 Mb if 50% good blocks are not defective. Two 512 Mb Flash memory chips can integrate a Flash storage device with 1 Gb or 128 MB capacity.

Accordingly, a system and method in accordance with the present invention provides for increased memory density within a particular space constraint by (1) providing multiple dies in a single memory package and (2) by providing stacked memory chips in a single PCB footprint. In so doing, the package/PCB will have increased memory density over a conventional package/PCB within the same space constraints, and the capacity of Flash storage devices is expanded accordingly.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A memory package comprising:
a substrate; and
a plurality of memory dies mounted on the substrate, each die having a separate chip enable.

2. The memory package of claim 1 wherein the plurality of memory dies are mounted on one side of the substrate.

3. The memory package of claim 1 wherein the plurality of memory dies are mounted on both sides of the substrate.

4. The memory package of claim 1 wherein the plurality of memory die are mounted as a stack on the substrate.

5. The memory package of claim 1 wherein the plurality of memory die are mounted in any combination of one side of the substrate, both sides of the substrate, stacked mounted on the substrate.

6. The memory package of claim 1 wherein the plurality of memory die comprise a plurality of Flash memory dies.

7. A chip architecture comprising:
a printed circuit board (PCB), the PCB including a footprint, the footprint including at least one no connect (NC) pad; and
a plurality of stacked memory chips mounted on the printed circuit board, each of the plurality of stacked memory having a chip enable signal pin and having at least one NC pin wherein at least one of the plurality of stacked memory chips utilizes an NC pin of another of the stacked memory chips to route the chip enable pin to at least one NC pad of the footprint.

8. The chip architecture of claim 7 wherein the plurality of stacked memory chips comprise a plurality of stacked Flash memory chips.

9. The chip architecture of claim 8 wherein the plurality of stacked Flash memory chips can be of a downgraded type.

10. The chip architecture comprising:
a printed circuit board (PCB), the PCB including a footprint, the footprint including a plurality of no connect (NC) pads; and
a plurality of stacked memory chips mounted on the PCB, each of the plurality of stacked memory chips including a chip enable signal, wherein one of the plurality of memory is coupled directly to the footprint of the PCB and its chip enable is coupled directly to the chip enable pad of the footprint, the remaining one of the plurality of stacked memory chips are coupled in a pin for pin fashion to the one memory chip except for their respective chip enable pin, wherein the chip enable pins for the remaining ones of the plurality of memory chips are routed to the plurality NC pins of the one stack memory chip and the plurality NC pads of the footprint.

11. The chip architecture of claim 10 wherein the plurality of stacked memory chips comprise a plurality of Flash memory chips.

12. The chip architecture of claim 11 wherein the plurality of stacked Flash memory chips can be of a downgraded type.
